(19) United States
(12) Patent Application Publication
(10) Pub. No.: US 2011/0058441 A1
(43) Pub. Date: Mar. 10, 2011

(54) DATA LINE DRIVING CIRCUIT

(75) Inventor: Keun Soo SONG, Icheon-si (KR)

(73) Assignee: HYNIX SEMICONDUCTOR INC., Icheon-si (KR)

(21) Appl. No.: 12/846,527

(22) Filed: Jul. 29, 2010

(30) Foreign Application Priority Data
Sep. 4, 2009 (KR) 10-2009-0083343

(51) Int. Cl. G11C 8/00

(52) U.S. Cl. 365/230.06

(57) ABSTRACT

A data line driving circuit includes: an operation period signal generation unit configured to generate an operation period signal for determining a write period and a read period in response to a read command or a write command; and a read data line driving unit configured to fix a read data line to a first voltage level in response to the operation period signal, the read data line being dedicated to a read operation.

### CROSS-REFERENCES TO RELATED APPLICATION

The present application claims priority under 35 U.S.C. §119(a) to Korean application number 10-2009-0083343, filed on Sep. 4, 2009, in the Korean Intellectual Property Office, which is incorporated herein by reference in its entirety as set forth in full.

### BACKGROUND

1. Technical Field

The present invention relates generally to semiconductor circuit technology, and more particularly to a data line driving circuit.

2. Related Art

A semiconductor memory includes a data line configured to transfer data. In a semiconductor memory, the data transfer efficiency and the layout margin are affected heavily by the data line layout design.

Therefore, the data line design occupies a large weight in the overall design of the semiconductor memory. Various types of data lines may be applied to various semiconductor memory designs depending on their type, and a variety of arrangement methods for the data lines may be applied.

Referring to FIG. 1, some data lines are dedicated to write operations (hereinafter, referred to as write data lines WGIO<0:N>), and other data lines are dedicated to read operations (hereinafter, referred to as read data lines RGIO<0:N>), and the write and read data lines may be formed separately depending on the semiconductor memory type.

Furthermore, when forming the data lines separately as described above, there are some layout advantages to alternately arrange the write data lines WGIO<0:N> and the read data lines RGIO<0:N> as shown in FIG. 1, because the write and read data lines follow the similar circuit paths at similar positions.

However, the alternating layout as shown in FIG. 1 will cause the coupling noise due to interference between the write data line WGIO<0:N> and the read data line RGIO<0:N> adjacent to each other. This will cause instability in the signal level integrity of the affected data lines.

For example, as shown in FIG. 2, the level of read data line is RGIO<0> adjacent to the write data line WGIO<0> may fluctuate due to the data transition of the write data line WGIO<0>, and the coupling noise may occur in the write data line WGIO<1> adjacent to the read data line RGIO<0>.

### SUMMARY

A data line driving circuit capable of reducing interference between adjacent data lines is described herein.

In an embodiment of the present invention, a data line driving circuit includes: an operation period signal generation unit configured to generate an operation period signal for determining a write period and a read period in response to a read command or a write command; and a read data line driving unit configured to fix a read data line to a first voltage level in response to the operation period signal, the read data line being dedicated to a read operation.

### BRIEF DESCRIPTION OF THE DRAWINGS

Features, aspects, and embodiments are described in conjunction with the attached drawings, in which:

FIG. 1 is a layout diagram illustrating arrangement of data lines;

FIG. 2 is a waveform diagram for explaining coupling noise between the data lines shown in FIG. 1;

FIG. 3 is a block diagram of a data line driving circuit according to an embodiment of the present invention;

FIG. 4 is a circuit diagram of an operation period signal generation unit of FIG. 3;

FIG. 5 is a output waveform diagram of the operation period signal generation unit of FIG. 4;

FIG. 6 is a circuit diagram of a read data line driving unit of FIG. 3; and

FIG. 7 is a circuit diagram of a write data line driving unit of FIG. 3.

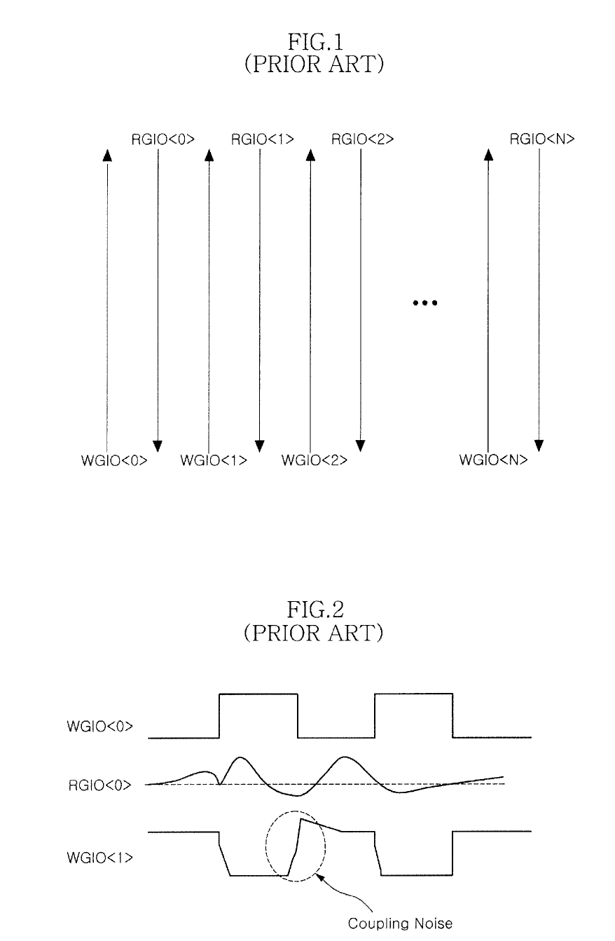

### DETAILED DESCRIPTION

Hereinafter, a data line driving circuit according to embodiments of the present invention will be described below with reference to the accompanying drawings through preferred embodiments.

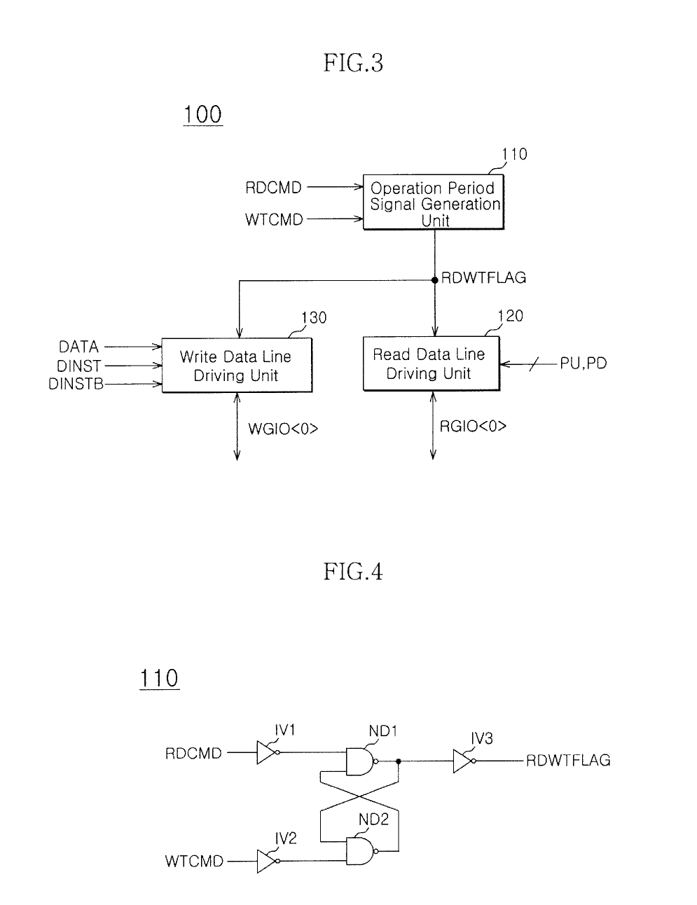

Referring to FIG. 3, a data line driving circuit 100 according to an embodiment of the present invention includes an operation period signal generation unit 110, a read data line driving unit 120, and a write data line driving unit 130.

The operation period signal generation unit 110 is configured to generate an operation period signal RDWTFLAG in to response to a read command RDCMD or a write command WTCMD.

The read data line driving unit 120 is configured to drive a read data line RGIO<0> to a predetermined level in response to a pull-up signal PU and a pull-down signal PD and would set the level of the read data line RGIO<0> to a ground voltage (VSS) level in is response to the operation period signal RDWTFLAG.

The write data line driving unit 130 is configured to drive a write data line WGIO<0> to a predetermined level in response to data input control signals DINST and DINSTB and would set the level of the write data line WGIO<0> to a power supply voltage (VDD) level.

FIG. 3 shows the circuit configuration for only one read data line RGIO<0> and one write data line WGIO<0>, but it should be readily understood that the read and write data line driving units 120, 130 are provided for all read and write data lines RGIO<0:N>, WGIO<0:N> as well. Since the operation period signal RDWTFLAG is commonly applied to the write and read date line driving units, one operation period signal generation unit 110 is needed; however, more than one operation period signal generation units 110 may be provided in consideration of the signal loading conditions of the operation period signal RDWTFLAG.

FIG. 4 is a circuit diagram for the operation period signal generation unit 110 according to an embodiment of the present invention. The operation period signal generation unit 110 may be configured in a RS flip-flop structure by using a plurality of inverters IV1, IV2, IV3 and a plurality of NAND gates ND1, ND2.

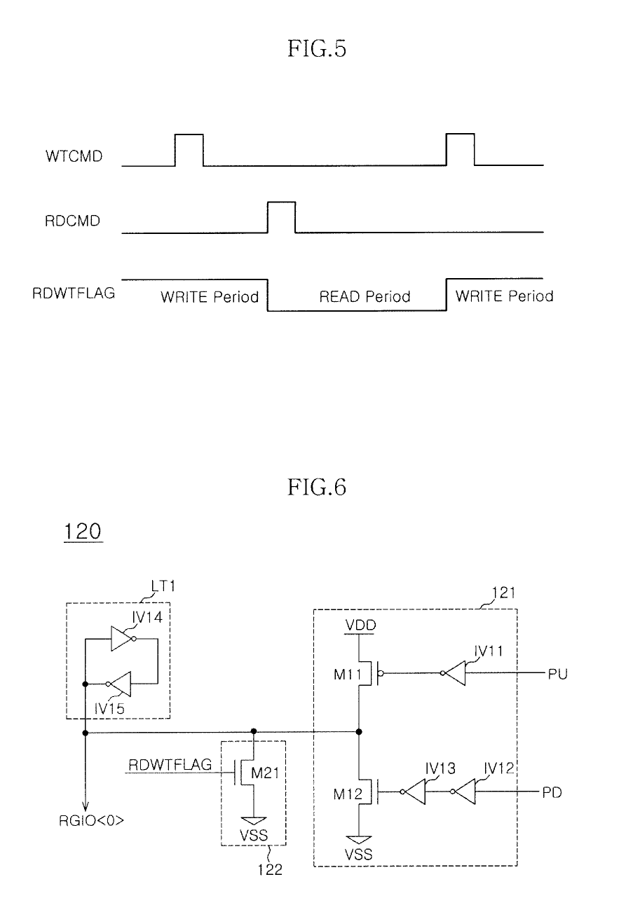

Since the operation period signal generation unit 110 has the RS flip-flop structure, now referring to FIG. 5, the operation period signal generation unit 110 outputs the operation period signal RDWTFLAG at a low level as the read command RDCMD is activated. When the write command WTCMD is activated, the operation period signal generation unit 110 outputs the operation period signal RDWTFLAG at a high level.

That is, the operation period signal RDWTFLAG maintains a high level during a write period and maintains a low level during a read period.

Referring to FIG. 6, the read data line driving unit 120 includes a latch LT1, a driver 121, and a data line controller 122.

The latch LT1 includes a plurality of inverters IV14 and IV15. The latch LT1 is configured to maintain the read data line RGIO<0> at the logic level of the last data.

The driver 121 includes a plurality of transistors M11, M12 and a plurality of inverters IV11, IV12, IV13. The driver 121 is configured to drive the read data line RGIO<0> to a power supply voltage (VDD) level or ground voltage (VSS) level in response to the pull-up signal PU and the pull-down signal PD.

The data line controller 122 is configured to set the read data line RGIO<0> to the ground voltage (VSS) level when the operation period signal RDWTFLAG is at a high level, that is, during the write period.

That is, by setting the read data lines RGIO<0:N> to the ground voltage (VSS) level during the write period by the data line driving circuit 100 according to an embodiment of the present invention, the coupling noise due to the interference from the adjacent write data line WGIO<0:N> can be prevented.

In this manner, the read data lines RGIO<0:N> can maintain stable data level during the write periods without interference from adjacent data lines.

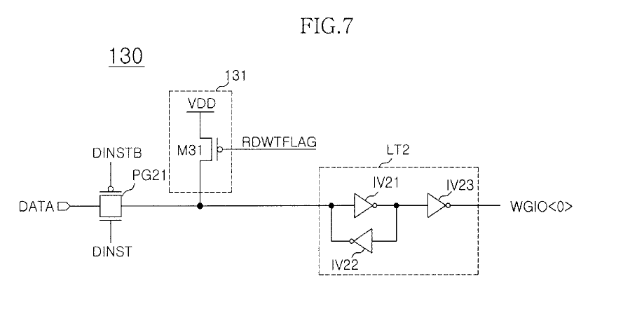

Referring to FIG. 7, the write data line driving unit 130 includes a pass gate PG21, a latch LT2, and a data line controller 131.

The pass gate PG21 is configured to pass data DATA externally inputted in accordance with the data input control signals DINST, DINSTB.

The latch LT2 includes a plurality of inverters IV21, IV22, IV23. The latch LT2 is configured to maintain the write data line WGIO<0> to the logic level of the last data.

The data line controller 131 is configured to set the write data line WGIO<0> to the power supply voltage (VDD) level when the operation period signal RDWTFLAG is at a low level, that is, during the read period.

That is, by setting the write data lines WGIO<0:N> to the power supply voltage (VDD) level during the read period by the data line driving circuit 100 according to an embodiment of the present invention, the coupling noise due to the interference from the adjacent read data line RGIO<0> can be prevented.

In this manner, the write data lines WGIO<0:N> can maintain stable data level during the read periods without interference from adjacent data lines.

In the data line driving circuit 100 according to an embodiment of the present invention, both the read and write data line driving units 120, 130 are configured to fixing the corresponding data line to a specific voltage level in order to prevent entirely or substantially the coupling noise due to the adjacent data lines.

However, it is also possible to accomplish the same task of preventing the coupling noise due to the adjacent data lines by configuring only the read data line driving unit 120 to set the corresponding data line to a specific voltage level.

That is, the write data driving unit 130 can be selectively not utilized at all or selectively utilized to set the corresponding data line to a specific voltage level.

The data line driving circuit 100 according to an embodiment of the present invention eliminates or reduces substantially the interference between adjacent data lines by floating a data line which does not operate to accomplish stable operations of the data line driving circuit.

While certain embodiments have been described above, it will be understood to those skilled in the art that the embodiments described are by way of example only. Accordingly, the data line driving circuit described herein should not be limited based on the described embodiments. Rather, the data line driving circuit described herein should only be limited in light of the claims that follow when taken in conjunction with the above description and accompanying drawings.

What is claimed is:

1. A data line driving circuit comprising:
an operation period signal generation unit configured to generate an operation period signal for determining a write period and a read period in response to a read command or a write command; and
a read data line driving unit configured to set a read data line to a first voltage level in response to the operation period signal, wherein the read data line is utilized for a read operation.

2. The data line driving circuit according to claim 1, further comprising a write data line driving unit configured to set a write data line to a second voltage level in response to the operation period is signal, wherein the write data line is utilized for a write operation.

3. The data line driving circuit according to claim 2, wherein the write data line driving unit comprises:
a pass gate configured to pass data to the write data line in response to a data input control signal; and
a data line controller configured to set the write data line to the second voltage level when the operation period signal maintains a level defining a read period.

4. The data line driving circuit according to claim 1, wherein the operation period signal generation unit comprises a flip-flop configured to receive the read command and the write command through first and second terminals thereof respectively and output the operation period signal through an output terminal thereof.

5. The data line driving circuit according to claim 4, wherein the write data line driving unit comprises:
a pass gate configured to pass data to the write data line in response to a data input control signal; and
a data line controller configured to set the write data line to the second voltage level when the operation period signal maintains a level defining a read period.

6. The data line driving circuit according to claim 5, further comprising a write data line driving unit configured to set a write data line to a second voltage level in response to the operation period signal, wherein the write data line is utilized for a write operation.

7. The data line driving circuit according to claim 1, wherein the read data line driving unit comprises:
a driver configured to drive the read data line to a power supply voltage level or ground voltage level in response to a pull-up signal or pull-down signal; and
a data line controller configured to fix the read data line to the first voltage level when the operation period signal maintains a level defining the write period.
